(19) United States
(12) Patent Application Publication
(10) Pub. No.: US 2022/0062955 A1
(43) Pub. Date: Mar. 3, 2022

(54) RETICLE POD CLEANSING APPARATUS

(71) Applicant: GUDENG PRECISION INDUSTRIAL CO., LTD., New Taipei City (TW)

(72) Inventors: CHIA-HO CHUANG, New Taipei City (TW); HSIN-MIN HSUEH, New Taipei City (TW); MING-CHIEN CHIU, New Taipei City (TW)

(21) Appl. No.: 17/088,605

(22) Filed: Nov. 4, 2020

(30) Foreign Application Priority Data
Sep. 1, 2020 (TW) 109129902

(51) Int. Cl. B08B 5/02; B08B 13/00; B08B 9/093; H01L 21/673; G03F 1/82

(52) U.S. Cl. CPC B08B 5/02; B08B 13/00; G03F 1/82; H01L 21/67359; H01L 21/67389; B08B 9/093

(57) ABSTRACT

A reticle pod cleansing apparatus includes a cavity, a gas injection unit, a dust counting unit and a control unit. The cavity has a chamber, an inlet opening in communication with the chamber, and an outlet opening in communication with the chamber. The gas injection unit is disposed at the chamber and is in communication with an inlet device through the inlet opening to inject gas into the chamber. The dust counting unit is in communication with the outlet opening to receive gas discharged from the outlet opening and calculate dust quantity of the gas discharged. The control unit is in signal communication with dust counting unit and adapted to send a signal when the calculated dust quantity is less than a predetermined threshold. During a cleansing process, the reticle pod cleansing apparatus detects precisely and instantly whether a reticle pod being cleansed has been sufficiently cleansed or not.

### CROSS-REFERENCE TO RELATED APPLICATION

This non-provisional application claims priority under 35 U.S.C. § 119(a) on Patent Application No(s). 109129902 filed in Taiwan, R.O.C. on Sep. 1, 2020, the entire contents of which are hereby incorporated by reference.

### BACKGROUND OF THE INVENTION

### 1. Field of the Invention

The present disclosure relates to cleansing apparatuses, and in particular to a reticle pod cleansing apparatus capable of detecting and calculating dust quantity.

### 2. Description of the Related Art

An advanced photolithography process of the semiconductor field, especially an Extreme Ultraviolet photolithography process, has extremely strict requirements for cleanliness of the process environment. If a reticle is contaminated with particles, the photolithography process will be defective. To meet the requirements for cleanliness and protect the reticles, reticle pods fend off external particles; thus, the cleanliness of the reticle pods is of vital importance. To this end, cleansing-oriented gas is admitted to reticle pods to remove therefrom particles. However, conventional reticle pod cleansing apparatuses (especially those dedicated to inner pods of reticle pods) are not capable of effectively confirming whether cleansed reticle pods have been sufficiently cleansed. Owing to the aforesaid failure to confirm whether cleansed reticle pods have been sufficiently cleansed, the reticle pods are likely to be a source of contamination of reticles therein.

In an attempt to overcome the aforesaid drawback of the prior art, cleansed reticle pods are rechecked, and then the rechecked reticle pods are returned to the reticle pod cleansing apparatuses for re-cleansing as needed, albeit inefficiently. By contrast, in order for a reticle pod to be thoroughly cleansed by a one-time cleansing process, the one-time cleansing process has to be lengthy to the detriment of energy efficiency and time effectiveness, especially when the reticle pod has been sufficiently cleansed.

### BRIEF SUMMARY OF THE INVENTION

An objective of the present disclosure is to provide a reticle pod cleansing apparatus capable of detecting and calculating dust quantity.

To achieve at least the above objective, the present disclosure provides a reticle pod cleansing apparatus, comprising: a cavity having a chamber, an inlet opening in communication with the chamber, and an outlet opening in communication with the chamber; a gas injection unit disposed at the chamber and being in communication with an inlet device through the inlet opening to inject gas into the chamber; a dust counting unit in communication with the outlet opening to receive gas discharged from the outlet opening and calculate dust quantity of the gas discharged; and a control unit being in signal communication with the dust counting unit and adapted to send a signal when the calculated dust quantity is less than a predetermined threshold.

In an embodiment of the present disclosure, the control unit is in signal communication with the inlet device, and the inlet device stops transferring gas to the chamber upon receipt of the signal.

In an embodiment of the present disclosure, the control unit is in signal communication with the gas injection unit, and the gas injection unit stops injecting gas into the chamber upon receipt of the signal.

In an embodiment of the present disclosure, the gas injection unit is an omnidirectional air knife nozzle.

In an embodiment of the present disclosure, the reticle pod cleansing apparatus further comprises a prompting device being in signal communication with the control unit and adapted to send a prompt upon receipt of the signal.

In an embodiment of the present disclosure, the reticle pod cleansing apparatus further comprises a filtering device disposed between the gas injection unit and the inlet device.

In an embodiment of the present disclosure, the reticle pod cleansing apparatus further comprises a holding device disposed in the chamber and adapted to hold a reticle pod.

In an embodiment of the present disclosure, the holding device has a wearproof portion in contact with the reticle pod.

In an embodiment of the present disclosure, the reticle pod cleansing apparatus further comprises a fixing device disposed in the chamber and adapted to fix a reticle pod in place.

In an embodiment of the present disclosure, the fixing device has a wearproof portion in contact with the reticle pod.

Therefore, during a cleansing process of the reticle pod, the reticle pod cleansing apparatus of the present disclosure detects precisely and instantly whether a reticle pod being cleansed has been sufficiently cleansed or not and determines whether to stop the cleansing process. The reticle pod cleansing apparatus of the present disclosure dispenses with the hassle of rechecking and returning to the cleansing process after the first cleansing process; thus, the reticle pod cleansing apparatus of the present disclosure is effective in simplifying and speeding up a cleansing process, cutting the cost incurred by the cleansing process, and preventing a waste of gas and energy which might otherwise result from lengthy, excessive cleansing.

### BRIEF DESCRIPTION OF THE DRAWINGS

FIG. 1 is a schematic view of a reticle pod cleansing apparatus according to an embodiment of the present disclosure.

FIG. 2 is a schematic view of a gas injection unit according to an embodiment of the present disclosure.

FIG. 3 is a schematic view of electronic signal communication relationship according to an embodiment of the present disclosure.

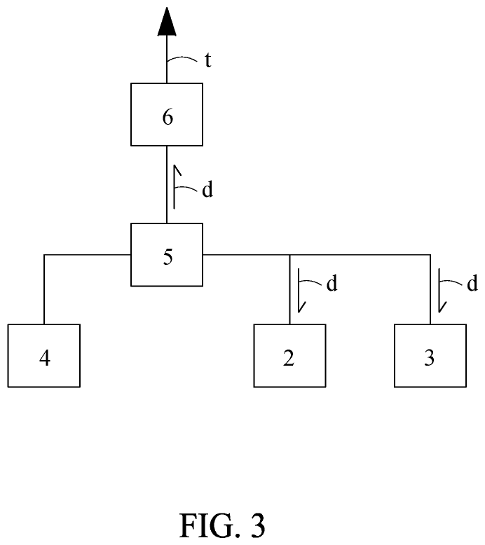

### DETAILED DESCRIPTION OF THE INVENTION

To facilitate understanding of the object, characteristics and effects of this present disclosure, embodiments together with the attached drawings for the detailed description of the present disclosure are provided.

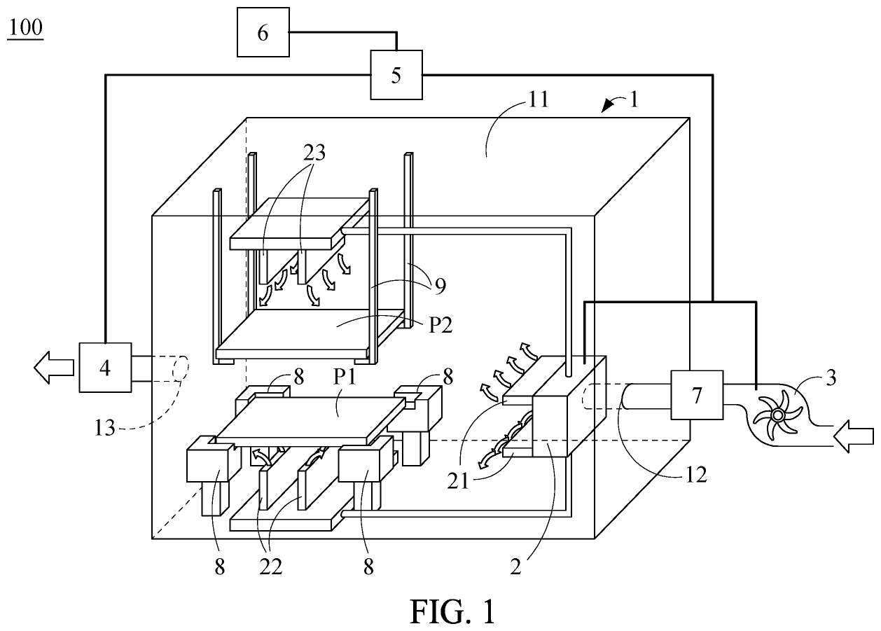

Referring to FIG. 1, in an embodiment of the present disclosure, a reticle pod cleansing apparatus 100 comprises a cavity 1, a gas injection unit 2, a dust counting unit 4 and a control unit 5.

The cavity 1 has a chamber 11, an inlet opening 12 in communication with the chamber 11, and an outlet opening 13 in communication with the chamber 11 to allow cleansing-oriented gas to enter the chamber 11 through the inlet opening 12 and exit the chamber 11 through the outlet opening 13. The chamber 11 contains a reticle to be cleansed and the gas injection unit 2.

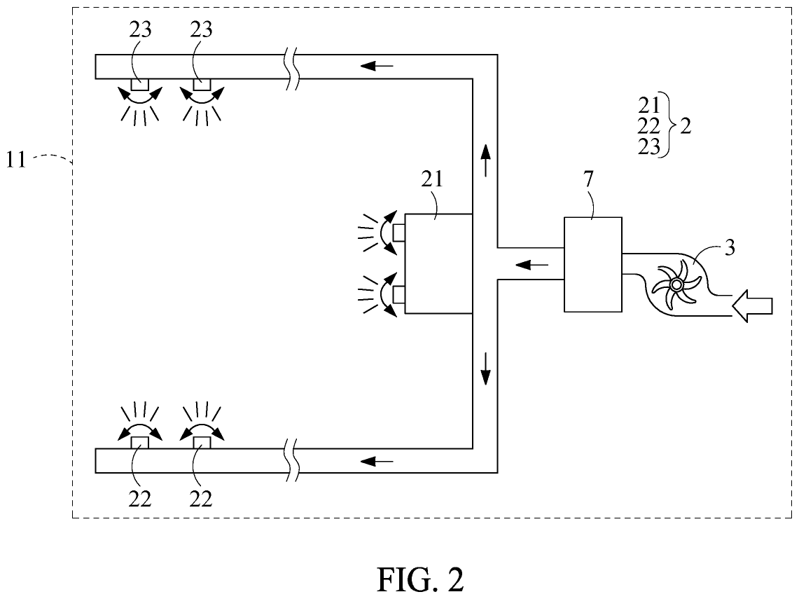

The gas injection unit 2 is disposed at the chamber 11. The gas injection unit 2 is in communication with an inlet device 3 through the inlet opening 12 to inject cleansing-oriented gas into the chamber 11 and thereby blow particles off the surface of the reticle. The inlet device 3 is, for example, a gas pump for delivering gas along a pipeline in a one-way manner toward the inlet opening 12. In this embodiment, as shown in FIG. 1 and FIG. 2, the gas injection unit 2 comprises a lateral injection element 21, a lower injection element 22 and an upper injection element 23. The lateral injection element 21, lower injection element 22 and upper injection element 23 are in communication with the inlet opening 12 to spray the gas from the inlet opening 12 from the lateral side, lower side and upper side of the reticle to the reticle so as to rinse the reticle. The lateral injection element 21, lower injection element 22 and upper injection element 23 each comprise a plurality of air nozzles for uniformly emanating air current. The lateral injection element 21, lower injection element 22 and upper injection element 23 are program-controllable omnidirectional air knife nozzles whose swing angles are determined by the control unit 5.

The dust counting unit 4 is in communication with the outlet opening 13. After going through the cleansing process of the reticle in the chamber 11, the waste gas is discharged from the outlet opening 13 and admitted to the dust counting unit 4. The dust counting unit 4 receives the particle-containing, waste gas from the outlet opening 13 and calculates its dust quantity. The dust counting unit 4 is, for example, an air particle counter for counting particles by the light scattering principle to detect the number of dust particles and particle diameter distribution per unit volume. The dust counting unit 4 can adjust selected wavelength of light wave in order to detect particles of a specific range of particle diameter. When air current discharged from the chamber 11 keeps passing through the outlet opening 13 and entering the dust counting unit 4, the dust counting unit 4 can continuously calculate the dust quantity within a detection range or sample, investigate into and detect at time intervals the dust quantity within a detection range.

The control unit 5 is in signal communication with the dust counting unit 4. The control unit 5 sends a stop signal d when the dust quantity calculated by the dust counting unit 4 is less than a predetermined threshold. The control unit 5 is a control circuit or control chip. The threshold is a standard absolute value or a value relative to the quantity of gas particles admitted to the inlet opening 12. Alternatively, the detected particle diameter is weighted and then compared with the threshold. Alternatively, the control unit 5 will send the stop signal d only if the quantity of all the gas particles which fall within every specific range of particle diameter is less than the threshold. Alternatively, the control unit 5 will send the stop signal d only if the quantity of all the gas particles which fall within only a specific range of particle diameter is less than the threshold. However, the present disclosure is not limited to the abovementioned.

In an embodiment, the reticle pod cleansing apparatus 100 further comprises the inlet device 3. The control unit 5 is in signal communication with the inlet device 3. When the inlet device 3 receives the stop signal d from the control unit 5, the inlet device 3 stops delivering gas to the chamber 11.

In another embodiment, the control unit 5 is in signal communication with the gas injection unit 2. The stop signal d sent from the control unit 5 can reach the gas injection unit 2. When the gas injection unit 2 receives the stop signal d, the gas injection unit 2 stops injecting gas into the chamber 11. In doing so, it is feasible to shut down the nozzles or cut off their communication with the inlet device 3.

In another embodiment, the reticle pod cleansing apparatus 100 further comprises a prompting device 6. The prompting device 6 is in signal communication with the control unit 5. When the prompting device 6 receives the stop signal d from the control unit 5, the prompting device 6 sends a stop prompt t to alert a related worker. The prompting device 6 is, for example, a display screen for displaying a prompt message “cleansing is done” to alert the worker, prompting the worker to shut down the inlet device 3 or the gas injection unit 2 by hand to take out the cleansed reticle pod. The prompting device 6 may also be a buzzing or audio device whereby the stop signal d received is converted into a prompt sound for alerting the worker. However, the present disclosure is not limited to the abovementioned.

With the dust counting unit 4 disposed at the outlet opening 13, the reticle pod cleansing apparatus 100 of the present disclosure can, during a cleansing process of a reticle pod, detect precisely and instantly whether the reticle pod being cleansed has been sufficiently cleansed or not and determine whether to stop the cleansing process. Furthermore, the reticle pod cleansing apparatus 100 of the present disclosure dispenses with the hassle of rechecking and returning to the cleansing process after the first cleansing process; thus, the reticle pod cleansing apparatus 100 of the present disclosure is effective in simplifying and speeding up a cleansing process, cutting the cost incurred by the cleansing process, and preventing a waste of gas and energy which might otherwise result from lengthy, excessive cleansing.

In this embodiment, as shown in FIG. 1, the reticle pod cleansing apparatus 100 further comprises a filtering device 7 disposed between the gas injection unit 2 and the inlet device 3. The filtering device 7 is provided in the form of a dense filter gauze and disposed in front of the inlet opening 12 (or on a route leading to the gas injection unit 2) to enable the gas to boost the cleansing performance once again after passing through the inlet device 3 and thus prevent the particles of the inlet device 3 from inflicting source-derived contamination on the chamber 11.

In this embodiment, the reticle pod cleansing apparatus 100 further comprises a holding device 8 and a fixing device 9. The holding device 8 and the fixing device 9 are disposed in the chamber 11. The holding device 8 holds a base P1 of a reticle pod. The fixing device 9 fixes a cover P2 of the reticle pod in place.

The holding device 8 is provided in the form of a plurality of support elements disposed at four corners of a region where the reticle pod lies, thereby supporting the base P1 of the reticle pod by means of the least contact area. The fixing device 9 is provided in the form of a plurality of clamping arms for clamping the cover P2 of the reticle pod from above the chamber 11. However, the present disclosure is not limited to the abovementioned. In a variant embodiment, the reticle pod cleansing apparatus 100 has just one of the holding device 8 and the fixing device 9, which holds the reticle pod entirely or clamps fixedly the reticle pod entirely.

In this embodiment, the size and quantity of the cavity 1, holding device 8 and fixing device 9 is subject to changes, and thus they are compatible with commercially-available reticle pods or any other containers, so as to meet different product needs.

In this embodiment, the holding device 8 and the fixing device 9 each have a wearproof portion in contact with the base P1 and the cover P2 of the reticle pod, respectively. The wearproof portions are made of one selected from the group consisting of polyvinyl chloride (PVC), poly(methyl methacrylate) (PMMA), polystyrene (PS), polyamide (PA), polyethylene (PE), polytetrafluoroethylene (PTFE), polypropylene (PP), acrylonitrile butadiene styrene (ABS), phenol formaldehyde resin (PF), urea-formaldehyde (UF), melamine-formaldehyde resin (MF), unsaturated polyester, epoxy resin, polyurethane (PU), polycarbonate (PC), polybutylene terephthalate (PBT), Nylon 66, Nylon 6, polyoxymethylene (POM), polyphenylene sulfide (PPS), polyether ether ketone (PEEK), polyamide-imide (PAI), polyetherimide (PEI), polyimide (PI), and a mixture thereof. Preferably, the wearproof portions are made of polyether ether ketone (PEEK).

While the present disclosure has been described by means of specific embodiments, numerous modifications and variations could be made thereto by those skilled in the art without departing from the scope and spirit of the present disclosure set forth in the claims.

What is claimed is:

1. A reticle pod cleansing apparatus, comprising:
a cavity having a chamber, an inlet opening in communication with the chamber, and an outlet opening in communication with the chamber;
a gas injection unit disposed at the chamber and being in communication with an inlet device through the inlet opening to inject gas into the chamber;
a dust counting unit in communication with the outlet opening to receive gas discharged from the outlet opening and calculate dust quantity of the gas discharged; and
a control unit being in signal communication with the dust counting unit and adapted to send a signal when the calculated dust quantity is less than a predetermined threshold.

2. The reticle pod cleansing apparatus of claim 1, wherein the control unit is in signal communication with the inlet device, and the inlet device stops transferring gas to the chamber upon receipt of the signal.

3. The reticle pod cleansing apparatus of claim 2, wherein the control unit is in signal communication with the gas injection unit, and the gas injection unit stops injecting gas into the chamber upon receipt of the signal.

4. The reticle pod cleansing apparatus of claim 3, further comprising a prompting device being in signal communication with the control unit and adapted to send a prompt upon receipt of the signal.

5. The reticle pod cleansing apparatus of claim 1, wherein the control unit is in signal communication with the gas injection unit, and the gas injection unit stops injecting gas into the chamber upon receipt of the signal.

6. The reticle pod cleansing apparatus of claim 1, wherein the gas injection unit is an omnidirectional air knife nozzle.

7. The reticle pod cleansing apparatus of claim 1, further comprising a filtering device disposed between the gas injection unit and the inlet device.

8. The reticle pod cleansing apparatus of claim 1, further comprising a holding device disposed in the chamber and adapted to hold a reticle pod.

9. The reticle pod cleansing apparatus of claim 8, wherein the holding device has a wearproof portion in contact with the reticle pod.

10. The reticle pod cleansing apparatus of claim 1, further comprising a fixing device disposed in the chamber and adapted to fix a reticle pod in place.

11. The reticle pod cleansing apparatus of claim 10, wherein the fixing device has a wearproof portion in contact with the reticle pod.
